(19) United States
(12) Patent Application Publication
(10) Pub. No.: US 2022/0246343 A1
(43) Pub. Date: Aug. 4, 2022

(54) MULTILAYER ELECTRONIC COMPONENT

(71) Applicant: TDK CORPORATION, Tokyo (JP)

(72) Inventor: Naoyuki MORI, Tokyo (JP)

(73) Assignee: TDK CORPORATION, Tokyo (JP)

(21) Appl. No.: 17/583,681

(22) Filed: Jan. 25, 2022

(30) Foreign Application Priority Data
Jan. 29, 2021 (JP) 2021-012953

(51) Int. Cl. H01F 27/28; H01F 27/29; H01F 27/40; H03H 7/00

(52) U.S. Cl. CPC H01F 27/2804; H01F 27/29; H01F 2027/2809; H03H 7/00; H01F 27/40

(57) ABSTRACT

An electronic component includes a common port, a signal port, a first inductor, a second inductor, and a stack. The first inductor has a first end and a second end. The second end of the first inductor is connected to one end of the second inductor. A first inductor conductor constituting the first inductor is wound about an axis extending in a first direction. A second inductor conductor constituting the second inductor is wound about an axis extending in a second direction intersecting the first direction.

### BACKGROUND OF THE INVENTION

### 1. Field of the Invention

The present invention relates to a multilayer electronic component including two inductors.

### 2. Description of the Related Art

Compact mobile communication apparatuses are generally configured to use a single common antenna for a plurality of applications that use different systems and have different service frequency bands, and to use a branching filter to separate a plurality of signals received and transmitted by the antenna from each other.

A branching filter for separating a first signal of a frequency within a first frequency band and a second signal of a frequency within a second frequency band higher than the first frequency band from each other typically includes a common port, a first signal port, a second signal port, a first filter provided in a first signal path leading from the common port to the first signal port, and a second filter provided in a second signal path leading from the common port to the second signal port. As the first and second filters, LC resonators including inductors and capacitors are used, for example.

Among known branching filters are ones that use a stack including a plurality of dielectric layers stacked together, as disclosed in US 2018/0006625 A1. An inductor known to be used in an LC resonator is one that is formed using an inductor electrode extending in a transverse direction of the stack and two via hole conductors extending in a stacking direction of the stack, as disclosed in US 2018/0006625 A1.

The recent market demands for reductions in size and footprint of the compact mobile communication apparatuses have also required miniaturization of branching filters for use in those communication apparatuses. If an LC resonator constituting a filter includes two inductors and the branching filter is reduced in size, electromagnetic coupling between the two inductors can be too strong. This has sometimes interfered with the implementation of desired characteristics.

US 2018/0006625 A1 discloses a method for reducing the electromagnetic coupling between two inductors each formed using an inductor electrode and two via hole conductors by shifting the two inductors relative to each other in a longitudinal direction of the top surface of the diplexer. However, since the miniaturization of the branching filter also decreases the space to shift the two inductors, the method described in US 2018/0006625 A1 is unable to sufficiently reduce the electromagnetic coupling between the two inductors in the miniaturized branching filter.

The foregoing problem is not limited to branching filters and applies to multilayer electronic components in general that include two inductors capable of electromagnetic coupling with each other.

### SUMMARY OF THE INVENTION

An object of the present invention is to provide a multilayer electronic component that can achieve desired characteristics by reducing electromagnetic coupling between two inductors.

A multilayer electronic component according to the present invention includes a first port, a second port that passes a signal input to the first port, a first inductor and a second inductor that are provided between the first port and the second port in a circuit configuration, and a stack that includes a plurality of dielectric layers and a plurality of conductors stacked together, the stack being intended to integrate the first port, the second port, the first inductor, and the second inductor. The first inductor has a first end closest to the first port in the circuit configuration, and a second end opposite to the first end. The second end of the first inductor is connected to one end of the second inductor.

The stack includes a first inductor conductor constituting the first inductor, and a second inductor conductor constituting the second inductor. The first inductor conductor is wound about an axis extending in a first direction. The second inductor conductor is wound about an axis extending in a second direction intersecting the first direction.

In the multilayer electronic component according to the present invention, the first direction and the second direction may be orthogonal to each other. In such a case, either one of the first and second directions may be parallel to the stacking direction of the plurality of dielectric layers.

In the multilayer electronic component according to the present invention, the first inductor and the second inductor may be provided in series in a path connecting the first port and the second port.

The multilayer electronic component according to the present invention may further include a first resonator provided between the first port and the second port in the circuit configuration. The first inductor and the second inductor may be included in the first resonator. In such a case, the multilayer electronic component may further include a third port and a second resonator provided between the first port and the third port in the circuit configuration.

If the multilayer electronic component according to the present invention includes the third port, either one of the second and third ports may be a first signal port that selectively passes a first signal of a frequency within a first passband, and the other of the second and third ports may be a second signal port that selectively passes a second signal of a frequency within a second passband lower than the first passband. The second port may be the first signal port, and the third port may be the second signal port.

If the multilayer electronic component according to the present invention includes the second resonator, the stack may further include a second resonator conductor constituting the second resonator. In such a case, either one of the first and second inductor conductors may be a horizontal inductor conductor wound about an axis extending in a direction parallel to the stacking direction of the plurality of dielectric layers, and the other of the first and second inductor conductors may be a vertical inductor conductor wound about an axis extending in a direction orthogonal to the stacking direction of the plurality of dielectric layers. The vertical inductor conductor may be located farther from the second resonator conductor than is the horizontal inductor conductor.

If the multilayer electronic component according to the present invention includes the second resonator, the stack may have a bottom surface and a top surface located at both ends of the plurality of dielectric layers in a stacking direction, and four side surfaces connecting the bottom surface and the top surface. The bottom surface and the top surface may each have a rectangular shape extending in one direction. The four side surfaces may include a first side surface and a second side surface located at both longitudinal ends of the rectangular shape. In such a case, either one of the first and second inductor conductors may be a horizontal inductor conductor wound about an axis extending in a direction parallel to the stacking direction of the plurality of dielectric layers. The other of the first and second inductor conductors may be a vertical inductor conductor wound about an axis extending in a direction orthogonal to the stacking direction of the plurality of dielectric layers. The vertical inductor conductor may be located closer to the first side surface than to the second side surface. The distance from the vertical inductor conductor to the first side surface may be smaller than the distance from the horizontal inductor conductor to the first side surface.

In the multilayer electronic component according to the present invention, the first inductor conductor constituting the first inductor is wound about the axis extending in the first direction, and the second inductor conductor constituting the second inductor is wound about the axis extending in the second direction intersecting the first direction. According to the present invention, the electromagnetic coupling between the first inductor and the second inductor can thereby be reduced to provide a multilayer electronic component that can achieve the desired characteristics.

Other and further objects, features and advantages of the present invention will appear more fully from the following description.

### BRIEF DESCRIPTION OF THE DRAWINGS

FIG. 1 is a circuit diagram showing circuit configuration of a multilayer electronic component according to an embodiment of the invention.

FIG. 2 is an external perspective view showing the multilayer electronic component according to the embodiment of the invention.

FIG. 3A to FIG. 3C are explanatory diagrams showing respective patterned surfaces of first to third dielectric layers of the stack of the multilayer electronic component according to the embodiment of the invention.

FIG. 4A to FIG. 4C are explanatory diagrams showing respective patterned surfaces of fourth to sixth dielectric layers of the stack of the multilayer electronic component according to the embodiment of the invention.

FIG. 5A is an explanatory diagram showing a patterned surface of a seventh dielectric layer of the stack of the multilayer electronic component according to the embodiment of the invention.

FIG. 5B is an explanatory diagram showing a patterned surface of each of eighth and ninth dielectric layers of the stack of the multilayer electronic component according to the embodiment of the invention.

FIG. 5C is an explanatory diagram showing a patterned surface of a tenth dielectric layer of the stack of the multilayer electronic component according to the embodiment of the invention.

FIG. 6A to FIG. 6C are explanatory diagrams showing respective patterned surfaces of eleventh to thirteenth dielectric layers of the stack of the multilayer electronic component according to the embodiment of the invention.

FIG. 7A to FIG. 7C are explanatory diagrams showing respective patterned surfaces of fourteenth to sixteenth dielectric layers of the stack of the multilayer electronic component according to the embodiment of the invention.

FIG. 8A and FIG. 8B are explanatory diagrams showing respective patterned surfaces of seventeenth and eighteenth dielectric layers of the stack of the multilayer electronic component according to the embodiment of the invention.

FIG. 8C is an explanatory diagram showing a patterned surface of each of a nineteenth and a twentieth dielectric layer of the stack of the multilayer electronic component according to the embodiment of the invention.

FIG. 9A to FIG. 9C are explanatory diagrams showing respective patterned surfaces of twenty-first to twenty-third dielectric layers of the stack of the multilayer electronic component according to the embodiment of the invention.

FIG. 10A to FIG. 10C are explanatory diagrams showing respective patterned surfaces of twenty-fourth to twenty-sixth dielectric layers of the stack of the multilayer electronic component according to the embodiment of the invention.

FIG. 11A to FIG. 11C are explanatory diagrams showing respective patterned surfaces of twenty-seventh to twenty-ninth dielectric layers of the stack of the multilayer electronic component according to the embodiment of the invention.

FIG. 12A and FIG. 12B are explanatory diagrams showing respective patterned surfaces of thirtieth to thirty-first dielectric layers of the stack of the multilayer electronic component according to the embodiment of the invention.

FIG. 13 is an internal perspective view showing the stack of the multilayer electronic component according to the embodiment of the invention.

FIG. 14 is a cross-sectional view showing a part of an inside of the stack shown in FIG. 13.

FIG. 15 is a characteristic diagram showing an example of pass characteristic and reflection characteristic of the multilayer electronic component according to the embodiment of the invention.

FIG. 16 is a characteristic diagram showing the insertion loss characteristic of a first filter of the embodiment of the invention.

FIG. 17 is a characteristic diagram showing the return loss characteristic of the first filter of the embodiment of the invention.

### DETAILED DESCRIPTION OF THE PREFERRED EMBODIMENTS

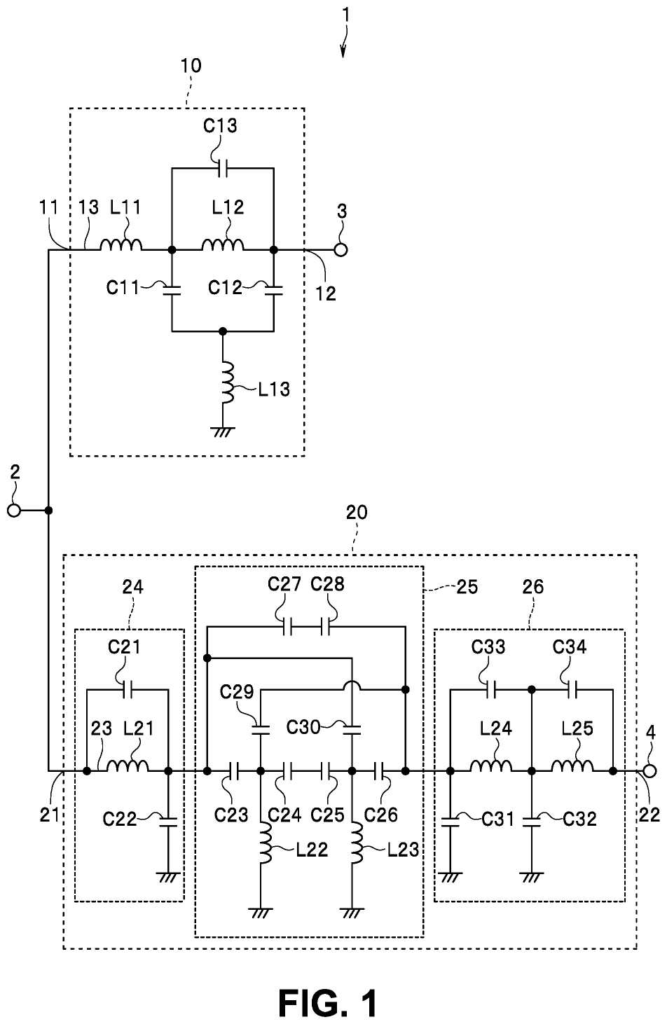

An embodiment of the present invention will now be described in detail with reference to the drawings. First, the configuration of a multilayer electronic component (hereinafter simply referred to as electronic component) 1 according to the embodiment of the invention will be outlined with reference to FIG. 1. The electronic component 1 according to the present embodiment includes at least a first port, a second port, a first inductor, and a second inductor. The second port is a port that passes a signal input to the first port. The first and second inductors are provided between the first port and the second port in a circuit configuration. In the present application, the expression of “in the (a) circuit configuration” is used to indicate not layout in physical configuration but layout in the circuit diagram.

FIG. 1 shows a branching filter (diplexer) as an example of the electronic component 1 including the first port, the second port, the first inductor, and the second inductor. The branching filter includes a first filter that selectively passes a first signal of a frequency within a first passband, and a second filter that selectively passes a second signal of a frequency within a second passband lower than the first passband.

The electronic component 1 further includes a third port. Either one of the second and third ports is a first signal port that selectively passes the first signal of the frequency within the first passband. The other of the second and third ports is a second signal port that selectively passes the second signal of the frequency within the second passband. In particular, in the present embodiment, the electronic component 1 includes a common port 2 serving as the first port, a signal port 4 serving as the second port, and a signal port 3 serving as the third port. The signal port 4 corresponds to the first signal port. The signal port 3 corresponds to the second signal port.

The electronic component 1 further includes a resonator 10 provided between the common port 2 and the signal port 3 in the circuit configuration, and a resonator 20 provided between the common port 2 and the signal port 4 in the circuit configuration.

Next, an example of the configuration of the resonators 10 and 20 will be described with reference to FIG. 1. The resonator 10 includes a port 11 connected to the common port 2, a port 12 connected to the signal port 3, a path 13 connecting the ports 11 and 12, inductors L11, L12, and L13, and capacitors C11, C12, and C13. The inductors L11 and L12 are provided in series in the path 13. The path 13 is a part of a path connecting the common port 2 and the signal port 3.

One end of the inductor L11 is connected to the port 11. One end of the inductor L12 is connected to the other end of the inductor L11, and the other end of the inductor L12 is connected to the port 12.

One end of the capacitor C11 is connected to the one end of the inductor L12. One end of the capacitor C12 is connected to the other end of the inductor L12. The inductor L13 connects the other end of each of the capacitors C11 and C12 to the ground. The capacitor C13 is connected in parallel with the inductor L12.

The resonator 20 includes a port 21 connected to the common port 2, a port 22 connected to the signal port 4, a path 23 connecting the ports 21 and 22, and LC circuits 24, 25, and 26 provided between the ports 21 and 22 in the circuit configuration.

The LC circuit 24 includes an inductor L21 and capacitors C21 and C22. One end of the inductor L21 is connected to the port 21. The capacitor C21 is connected in parallel with the inductor L21. One end of the capacitor C22 is connected to the other end of the inductor L21. The other end of the capacitor C22 is grounded.

The LC circuit 25 includes inductors L22 and L23 and capacitors C23, C24, C25, C26, C27, C28, C29 and C30. One end of the capacitor C23 is connected to the other end of the inductor L21 of the LC circuit 24. One end of the capacitor C24 is connected to the other end of the capacitor C23. One end of the capacitor C25 is connected to the other end of the capacitor C24. One end of the capacitor C26 is connected to the other end of the capacitor C25.

One end of the capacitor C27 is connected to the one end of the capacitor C23. One end of the capacitor C28 is connected to the other end of the capacitor C27. The other end of the capacitor C28 is connected to the other end of the capacitor C26.

One end of the capacitor C29 is connected to the connection point between the capacitors C23 and C24. The other end of the capacitor C29 is connected to the connection point between the capacitors C26 and C28. One end of the inductor L22 is connected to the connection point between the capacitors C23 and C24. The other end of the inductor L22 is grounded.

One end of the capacitor C30 is connected to the connection point between the capacitors C23 and C27. The other end of the capacitor C30 is connected to the connection point between the capacitors C25 and C26. One end of the inductor L23 is connected to the connection point between the capacitors C25 and C26. The other end of the inductor L23 is grounded.

The LC circuit 26 includes inductors L24 and L25 and capacitors C31, C32, C33 and C34. The inductors L24 and L25 are provided in series in the path 23. The path 23 is a part of a path connecting the common port 2 and the signal port 4.

One end of the inductor L24 is connected to the other end of the capacitor C26 of the LC circuit 25. One end of the inductor L25 is connected to the other end of the inductor L24. The other end of the inductor L25 is connected to the port 22.

One end of the capacitor C31 is connected to the one end of the inductor L24. One end of the capacitor C32 is connected to the one end of the inductor L25. The other end of each of the capacitors C31 and C32 is grounded. The capacitor C33 is connected in parallel with the inductor L24. The capacitor C34 is connected in parallel with the inductor L25.

The first signal of the frequency within the first passband passes selectively through the path 23 of the resonator 20. The second signal of the frequency within the second passband passes selectively through the path 13 of the resonator 10. In such a manner, the electronic component 1 separates the first signal and the second signal.

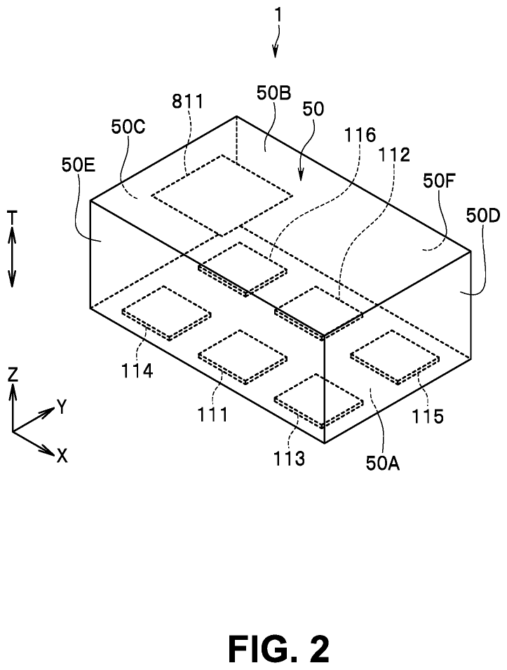

Next, other configurations of the electronic component 1 will be described with reference to FIG. 2. FIG. 2 is a perspective view showing the appearance of the electronic component 1.

The electronic component 1 further includes a stack 50 including a plurality of dielectric layers and a plurality of conductors stacked together. The stack 50 is intended to integrate the first port, the second port, the third port, the first inductor, and the second inductor. In particular, in the present embodiment, the stack 50 integrates the common port 2, the signal ports 3 and 4, and the resonators 10 and 20. The resonators 10 and 20 are formed using the plurality of conductors.

The stack 50 has a bottom surface 50A and a top surface 50B located at both ends in a stacking direction T of the plurality of dielectric layers, and four side surfaces 50C to 50F connecting the bottom surface 50A and the top surface 50B. The side surfaces 50C and 50D are opposite to each other. The side surfaces 50E and 50F are opposite to each other. The side surfaces 50C to 50F are perpendicular to the top surface 50B and the bottom surface 50A.

Here, X, Y, and Z directions are defined as shown in FIG. 2. The X, Y, and Z directions are orthogonal to one another. In the present embodiment, a direction parallel to the stacking direction T will be referred to as the Z direction. The opposite directions to the X, Y, and Z directions are defined as −X, −Y, and −Z directions, respectively.

As shown in FIG. 2, the bottom surface 50A is located at the end of the stack 50 in the −Z direction. The top surface 50B is located at the end of the stack 50 in the Z direction. The bottom surface 50A and the top surface 50B each have a rectangular shape extending in the X direction. The side surface 50C is located at the end of the stack 50 in the −X direction. The side surface 50D is located at the end of the stack 50 in the X direction. The side surface 50E is located at the end of the stack 50 in the −Y direction. The side surface 50F is located at the end of the stack 50 in the Y direction.

The electronic component 1 further includes terminals 111, 112, 113, 114, 115, and 116 located on the bottom surface 50A of the stack 50. The terminals 114, 111, and 113 are arranged in this order in the X direction at positions closer to the side surface 50E than to the side surface 50F. The terminals 116, 112, and 115 are arranged in this order in the X direction at positions closer to the side surface 50F than to the side surface 50E.

The terminal 112 corresponds to the common port 2, the terminal 113 to the signal port 3, and the terminal 114 to the signal port 4. The common port 2 and the signal ports 3 and 4 are thus provided on the bottom surface 50A of the stack 50. Each of the terminals 111, 115 to 116 is grounded.

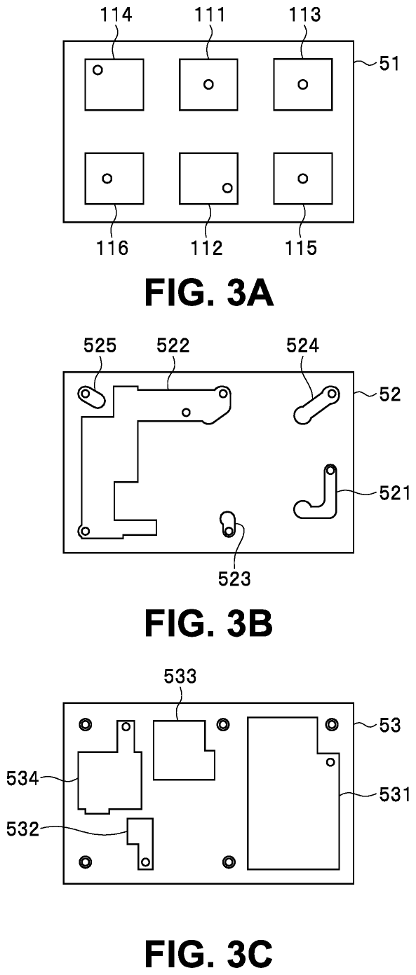

Next, an example of the plurality of dielectric layers and the plurality of conductors constituting the stack 50 will be described with reference to FIGS. 3A to 13. In this example, the stack 50 includes thirty-one dielectric layers stacked together. The thirty-one dielectric layers will be referred to as a first to a thirty-first dielectric layer in the order from bottom to top. The first to thirty-first dielectric layers are denoted by reference numerals 51 to 81, respectively.

In FIG. 3A to FIG. 11C, each circle represents a through hole. The dielectric layers 51 to 79 each have a plurality of through holes. The through holes are each formed by filling a hole intended for a through hole with a conductive paste. Each of the through holes is connected to a conductor layer or another through hole.

FIG. 3A shows the patterned surface of the first dielectric layer 51. The terminals 111 to 116 are formed on the patterned surface of the dielectric layer 51.

FIG. 3B shows the patterned surface of the second dielectric layer 52. Conductor layers 521, 522, 523, 524 and 525 are formed on the patterned surface of the dielectric layer 52.

FIG. 3C shows the patterned surface of the third dielectric layer 53. Conductor layers 531, 532, 533 and 534 are formed on the patterned surface of the dielectric layer 53.

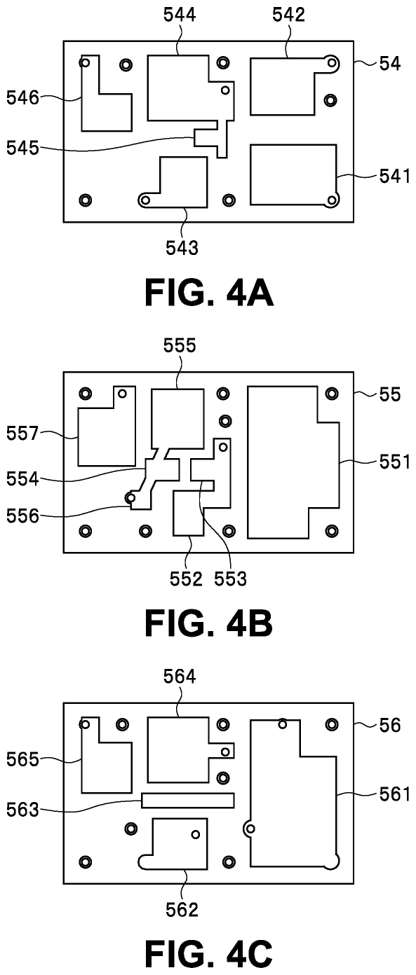

FIG. 4A shows the patterned surface of the fourth dielectric layer 54. Conductor layers 541, 542, 543, 544, 545 and 546 are formed on the patterned surface of the dielectric layer 54. The conductor layer 545 is connected to the conductor layer 544.

FIG. 4B shows the patterned surface of the fifth dielectric layer 55. Conductor layers 551, 552, 553, 554, 555, 556 and 557 are formed on the patterned surface of the dielectric layer 55. The conductor layer 553 is connected to the conductor layer 552. The conductor layers 555 and 556 are connected to the conductor layer 554.

FIG. 4C shows the patterned surface of the sixth dielectric layer 56. Conductor layers 561, 562, 563, 564 and 565 are formed on the patterned surface of the dielectric layer 56.

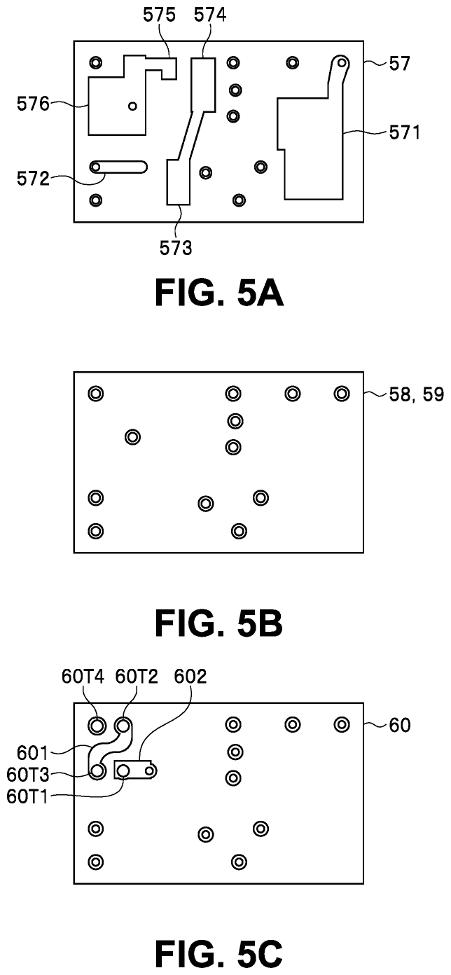

FIG. 5A shows the patterned surface of the seventh dielectric layer 57. Conductor layers 571, 572, 573, 574, 575 and 576 are formed on the patterned surface of the dielectric layer 57. The conductor layer 574 is connected to the conductor layer 573. The conductor layer 576 is connected to the conductor layer 575.

FIG. 5B shows the patterned surface of each of the eighth and ninth dielectric layers 58 and 59. No conductor layer is formed on the patterned surface of each of the dielectric layers 58 and 59.

FIG. 5C shows the patterned surface of the tenth dielectric layer 60. Conductor layers 601 and 602 are formed on the patterned surface of the dielectric layer 60. In FIG. 5C, the reference numerals 60T1, 60T2, 60T3, and 60T4 denote inductor through holes formed in the dielectric layer 60.

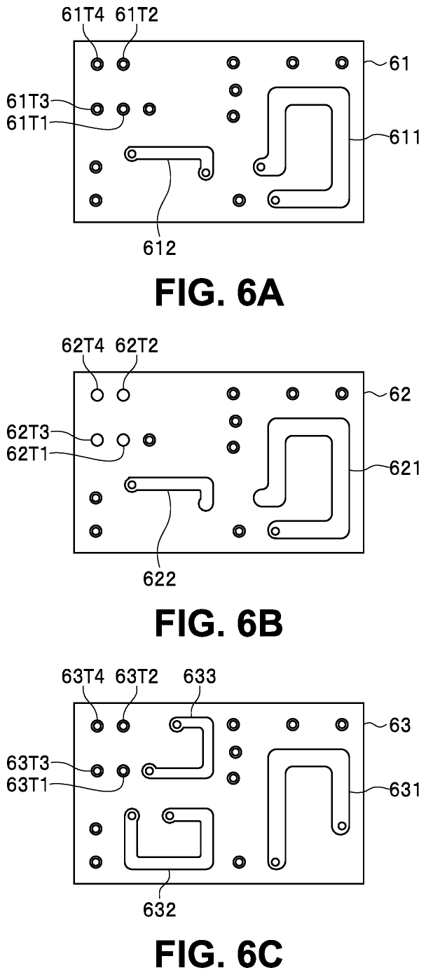

FIG. 6A shows the patterned surface of the eleventh dielectric layer 61. Conductor layers 611 and 612 are formed on the patterned surface of the dielectric layer 61. In FIG. 6A, the reference numerals 61T1, 61T2, 61T3, and 61T4 denote inductor through holes formed in the dielectric layer 61.

FIG. 6B shows the patterned surface of the twelfth dielectric layer 62. Conductor layers 621 and 622 are formed on the patterned surface of the dielectric layer 62. In FIG. 6B, the reference numerals 62T1, 62T2, 62T3, and 62T4 denote inductor through holes formed in the dielectric layer 62.

FIG. 6C shows the patterned surface of the thirteenth dielectric layer 63. Conductor layers 631, 632 and 633 are formed on the patterned surface of the dielectric layer 63. In FIG. 6C, the reference numerals 63T1, 63T2, 63T3, and 63T4 denote inductor through holes formed in the dielectric layer 63.

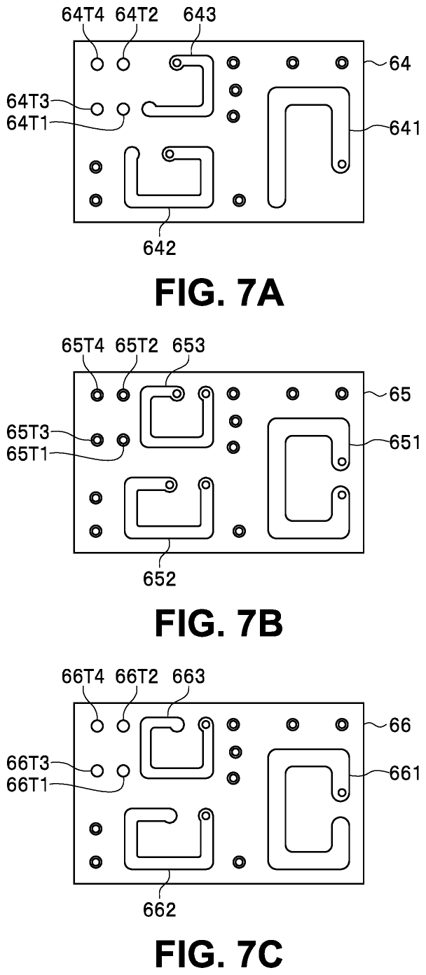

FIG. 7A shows the patterned surface of the fourteenth dielectric layer 64. Conductor layers 641, 642 and 643 are formed on the patterned surface of the dielectric layer 64. In FIG. 7A, the reference numerals 64T1, 64T2, 64T3, and 64T4 denote inductor through holes formed in the dielectric layer 64.

FIG. 7B shows the patterned surface of the fifteenth dielectric layer 65. Conductor layers 651, 652 and 653 are formed on the patterned surface of the dielectric layer 65. In FIG. 7B, the reference numerals 65T1, 65T2, 65T3, and 65T4 denote inductor through holes formed in the dielectric layer 65.

FIG. 7C shows the patterned surface of the sixteenth dielectric layer 66. Conductor layers 661, 662 and 663 are formed on the patterned surface of the dielectric layer 66. In FIG. 7C, the reference numerals 66T1, 66T2, 66T3, and 66T4 denote inductor through holes formed in the dielectric layer 66.

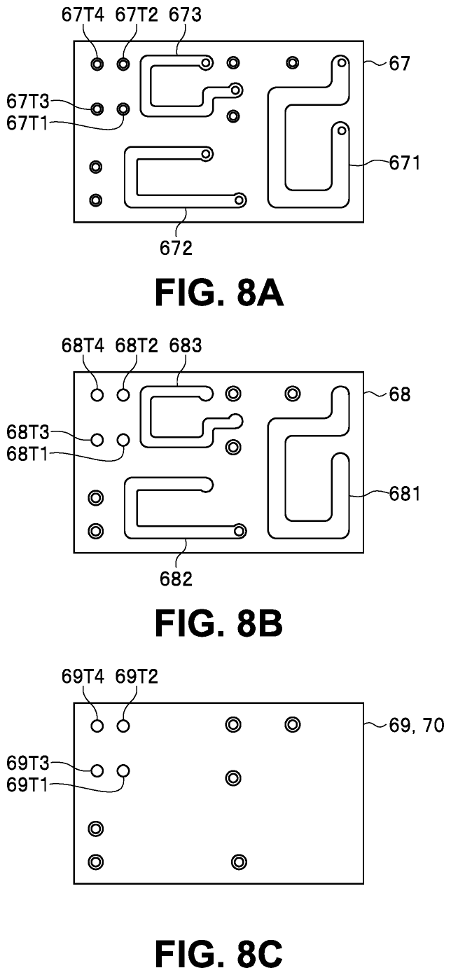

FIG. 8A shows the patterned surface of the seventeenth dielectric layer 67. Conductor layers 671, 672 and 673 are formed on the patterned surface of the dielectric layer 67. In FIG. 8A, the reference numerals 67T1, 67T2, 67T3, and 67T4 denote inductor through holes formed in the dielectric layer 67.

FIG. 8B shows the patterned surface of the eighteenth dielectric layer 68. Conductor layers 681, 682 and 683 are formed on the patterned surface of the dielectric layer 68. In FIG. 8B, the reference numerals 68T1, 68T2, 68T3, and 68T4 denote inductor through holes formed in the dielectric layer 68.

FIG. 8C shows the patterned surface of each of the nineteenth and twentieth dielectric layers 69 and 70. No conductor layer is formed on the patterned surface of each of the dielectric layers 69 and 70. In FIG. 8C, the reference numerals 69T1, 69T2, 69T3, and 69T4 denote inductor through holes formed in the dielectric layers 69 and 70.

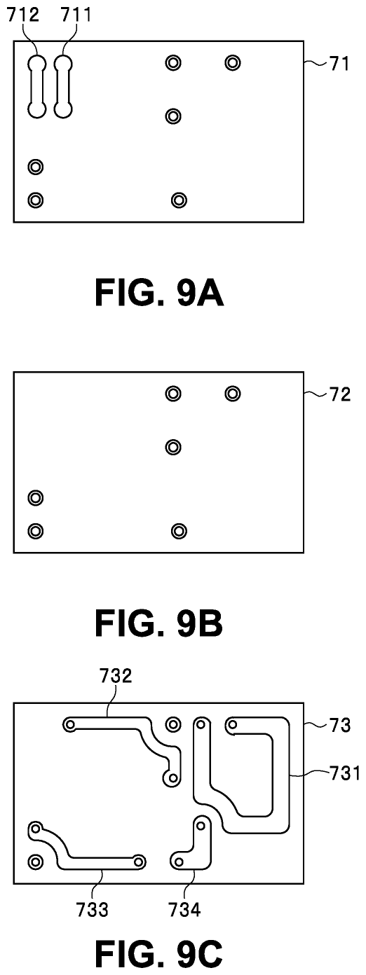

FIG. 9A shows the patterned surface of the twenty-first dielectric layer 71. Conductor layers 711 and 712 are formed on the patterned surface of the dielectric layer 71.

FIG. 9B shows the patterned surface of the twenty-second dielectric layer 72. No conductor layer is formed on the patterned surface of the dielectric layer 72.

FIG. 9C shows the patterned surface of the twenty-third dielectric layer 73. Conductor layers 731, 732, 733 and 734 are formed on the patterned surface of the dielectric layer 73.

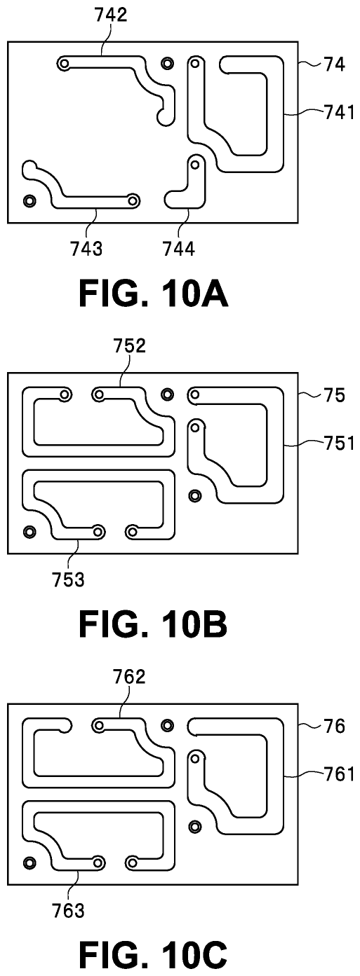

FIG. 10A shows the patterned surface of the twenty-fourth dielectric layer 74. Conductor layers 741, 742, 743 and 744 are formed on the patterned surface of the dielectric layer 74.

FIG. 10B shows the patterned surface of the twenty-fifth dielectric layer 75. Conductor layers 751, 752 and 753 are formed on the patterned surface of the dielectric layer 75.

FIG. 10C shows the patterned surface of the twenty-sixth dielectric layer 76. Conductor layers 761, 762 and 763 are formed on the patterned surface of the dielectric layer 76.

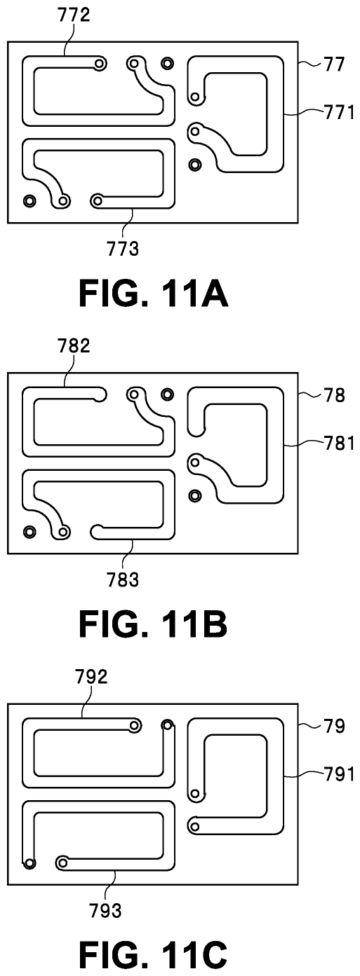

FIG. 11A shows the patterned surface of the twenty-seventh dielectric layer 77. Conductor layers 771, 772 and 773 are formed on the patterned surface of the dielectric layer 77.

FIG. 11B shows the patterned surface of the twenty-eighth dielectric layer 78. Conductor layers 781, 782 and 783 are formed on the patterned surface of the dielectric layer 78.

FIG. 11C shows the patterned surface of the twenty-ninth dielectric layer 79. Conductor layers 791, 792 and 793 are formed on the patterned surface of the dielectric layer 79.

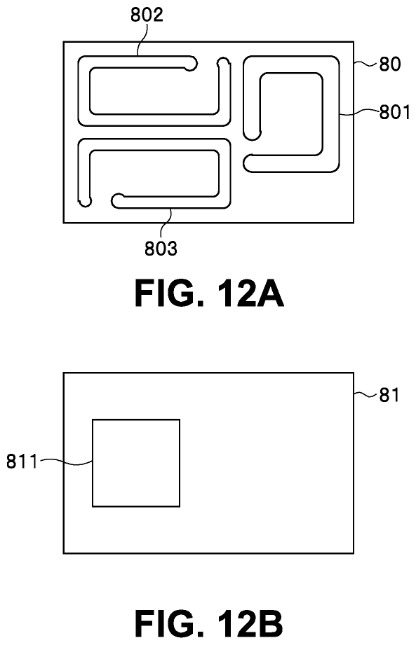

FIG. 12A shows the patterned surface of the thirtieth dielectric layer 80. Conductor layers 801, 802 and 803 are formed on the patterned surface of the dielectric layer 80.

FIG. 12B shows the patterned surface of the thirty-first dielectric layer 81. A mark 811 made of a conductor layer is formed on the patterned surface of the dielectric layer 81.

The stack 50 shown in FIG. 2 is formed by stacking the first to thirty-first dielectric layers 51 to 81 such that the patterned surface of the first dielectric layer 51 serves as the bottom surface 50A of the stack 50 and the surface of the thirty-first dielectric layer 81 opposite to the patterned surface thereof serves as the top surface 50B of the stack 50.

Each of the plurality of through holes shown in FIGS. 3A to 11C is connected to, when the first to twenty-ninth dielectric layers 51 to 79 are stacked, a conductor layer overlapping in the stacking direction T or to another through hole overlapping in the stacking direction T. Of the plurality of through holes shown in FIGS. 3A to 11C, the ones located within a terminal or a conductor layer are connected to the terminal or conductor layer.

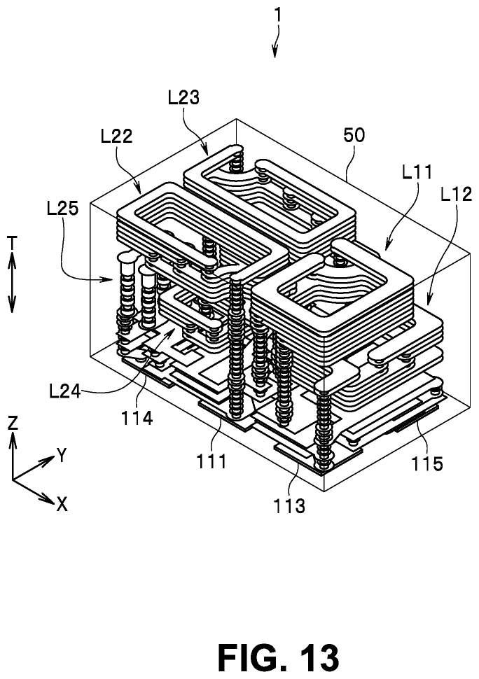

FIG. 13 shows the inside of the stack 50 formed by stacking the first to thirty-first dielectric layers 51 to 81. As shown in FIG. 13, the plurality of conductor layers and the plurality of through holes shown in FIGS. 3A to 12B are stacked together inside the stack 50. In FIG. 13, the mark 811 is omitted. For ease of understanding, FIG. 13 shows the stack 50 greater than its actual dimension in the stacking direction T.

Correspondences between the circuit components of the electronic component 1 shown in FIG. 1 and the internal components of the stack 50 shown in FIG. 3A to FIG. 12B will now be described. The components of the resonator 10 will initially be described. The inductor L11 is composed of the conductor layers 731, 741, 751, 761, 771, 781, 791 and 801 shown in FIG. 9C to FIG. 12A and the through holes connected to those conductor layers.

The inductor L12 is composed of the conductor layers 611, 621, 631, 641, 651, 661, 671 and 681 shown in FIG. 6A to FIG. 8B and the through holes connected to those conductor layers.

The inductor L13 is composed of the conductor layer 521 shown in FIG. 3B.

The capacitor C11 is composed of the conductor layers 531, 541, 551 and 561 shown in FIG. 3C to FIG. 4C, and the dielectric layers 53 to 55 each interposed between two of those conductor layers.

The capacitor C12 is composed of the conductor layers 531, 542 and 551 shown in FIG. 3C to FIG. 4B, and the dielectric layers 53 and 54 each interposed between two of those conductor layers.

The capacitor C13 is composed of the conductor layers 561 and 571 shown in FIG. 4C and FIG. 5A, and the dielectric layer 56 interposed between those conductor layers.

Next, the components of the LC circuit 24 of the resonator 20 will be described. The inductor L21 is composed of the conductor layers 612, 622, 632, 642, 652, 662, 672 and 682 shown in FIG. 6A to FIG. 8B and the through holes connected to those conductor layers.

The capacitor C21 is composed of the terminal 112 and the conductor layer 543 shown in FIG. 3A and FIG. 4A, and the dielectric layers 51 to 53 each interposed between the terminal 112 and the conductor layer 543.

The capacitor C22 is composed of the terminal 116 and the conductor layer 532 shown in FIG. 3A and FIG. 3C, and the dielectric layers 51 and 52 each interposed between the terminal 116 and the conductor layer 532.

Next, the components of the LC circuit 25 of the resonator 20 will be described. The inductor L22 is composed of the conductor layers 732, 742, 752, 762, 772, 782, 792 and 802 shown in FIG. 9C to FIG. 12A and the through holes connected to those conductor layers.

The inductor L23 is composed of the conductor layers 733, 743, 753, 763, 773, 783, 793 and 803 shown in FIG. 9C to FIG. 12A and the through holes connected to those conductor layers.

The capacitor C23 is composed of the conductor layers 543, 552 and 562 shown in FIG. 4A to FIG. 4C, and the dielectric layers 54 and 55 each interposed between two of those conductor layers.

The capacitor C24 is composed of the conductor layers 553 and 563 shown in FIG. 4B and FIG. 4C, and the dielectric layer 55 interposed between those conductor layers.

The capacitor C25 is composed of the conductor layers 554 and 563 shown in FIG. 4B and FIG. 4C, and the dielectric layer 55 interposed between those conductor layers.

The capacitor C26 is composed of the conductor layers 544, 555 and 564 shown in FIG. 4A to FIG. 4C, and the dielectric layers 54 and 55 each interposed between two of those conductor layers.

The capacitor C27 is composed of the conductor layers 562 and 573 shown in FIG. 4C and FIG. 5A, and the dielectric layer 56 interposed between those conductor layers.

The capacitor C28 is composed of the conductor layers 564 and 574 shown in FIG. 4C and FIG. 5A, and the dielectric layer 56 interposed between those conductor layers.

The capacitor C29 is composed of the conductor layers 545 and 553 shown in FIG. 4A and FIG. 4B, and the dielectric layer 54 interposed between those conductor layers.

The capacitor C30 is composed of the conductor layers 532 and 556 shown in FIG. 3C to FIG. 4B, and the dielectric layers 54 and 55 each interposed between those conductor layers.

Next, the components of the LC circuit 26 of the resonator 20 will be described. The inductor L24 is composed of the conductor layers 633, 643, 653, 663, 673 and 683 shown in FIG. 6C to FIG. 8B and the through holes connected to those conductor layers.

The inductor L25 is composed of the conductor layers 601, 711, and 712 shown in FIG. 5C to FIG. 9A and the through holes 60T1 to 60T4, 61T1 to 61T4, 62T1 to 62T4, 63T1 to 63T4, 64T1 to 64T4, 65T1 to 65T4, 66T1 to 66T4, 67T1 to 67T4, 68T1 to 68T4, and 69T1 to 69T4 shown in FIG. 5C to FIG. 9A.

The through holes 60T1, 61T1, 62T1, 63T1, 64T1, 65T1, 66T1, 67T1, 68T1, and 69T1 are connected in series. The through holes 60T2, 61T2, 62T2, 63T2, 64T2, 65T2, 66T2, 67T2, 68T2, and 69T2 are connected in series. The through holes 60T3, 61T3, 62T3, 63T3, 64T3, 65T3, 66T3, 67T3, 68T3, and 69T3 are connected in series. The through holes 60T4, 61T4, 62T4, 63T4, 64T4, 65T4, 66T4, 67T4, 68T4, and 69T4 are connected in series.

The through hole 69T1 formed in the dielectric layer 70 is connected to a portion of the conductor layer 711 near one end. The through hole 69T2 formed in the dielectric layer 70 is connected to a portion of the conductor layer 711 near the other end. The through hole 60T2 formed in the dielectric layer 60 is connected to a portion of the conductor layer 601 near one end. The through hole 60T3 formed in the dielectric layer 60 is connected to a portion of the conductor layer 601 near the other end. The through hole 69T3 formed in the dielectric layer 70 is connected to a portion of the conductor layer 712 near one end. The through hole 69T4 formed in the dielectric layer 70 is connected to a portion of the conductor layer 712 near the other end.

The capacitor C31 is composed of the conductor layers 533 and 544 shown in FIG. 3C and FIG. 4A, and the dielectric layer 53 interposed between those conductor layers.

The capacitor C32 is composed of the conductor layers 522 and 534 shown in FIG. 3B and FIG. 3C, and the dielectric layer 52 interposed between those conductor layers.

The capacitor C33 is composed of the conductor layers 564 and 575 shown in FIG. 4C and FIG. 5A, and the dielectric layer 56 interposed between those conductor layers.

The capacitor C34 is composed of the conductor layers 534, 546, 557, 565 and 576 shown in FIG. 3C to FIG. 5A, and the dielectric layers 53 to 56 each interposed between two of those conductor layers.

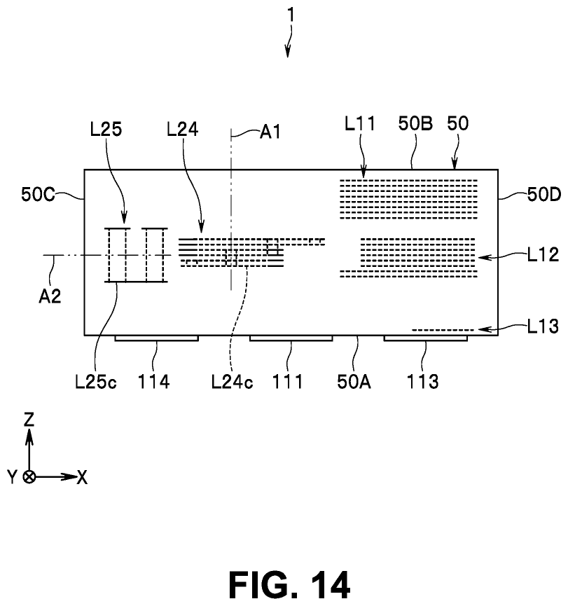

Next, structural features of the electronic component 1 according to the present embodiment will be described with reference to FIGS. 1, 13, and 14. FIG. 14 is a cross-sectional view showing a part of the inside of the stack 50 shown in FIG. 13. In the present embodiment, the inductor L24 of the LC circuit 26 in the resonator 20 corresponds to the first inductor, and the inductor L25 of the LC circuit 26 in the resonator 20 corresponds to the second inductor.

The inductors L24 and L25 will hereinafter also be referred to as a first inductor L24 and a second inductor L25, respectively. As shown in FIG. 1, the first inductor L24 and the second inductor L25 are included in the resonator 20, and are provided in series in the path 23 of the resonator 20. The path 23 is a part of the path connecting the common port 2 (first port) and the signal port 4 (second port). The first inductor L24 has a first end closest to the common port 2 (first port) in the circuit configuration, and a second end that is opposite to the first end. The second end of the first inductor L24 is connected to one end of the second inductor L25.

The stack 50 includes a first inductor conductor L24c constituting the first inductor L24 and a second inductor conductor L25c constituting the second inductor L25. The first inductor conductor L24c is a structure of conductors formed of the conductor layers 633, 643, 653, 663, 673, and 683, and a plurality of through holes connected to these conductor layers. The second inductor conductor L25c is a structure of conductors formed of the conductor layers 601, 711, and 712, and the through holes 60T1 to 60T4, 61T1 to 61T4, 62T1 to 62T4, 63T1 to 63T4, 64T1 to 64T4, 65T1 to 65T4, 66T1 to 66T4, 67T1 to 67T4, 68T1 to 68T4, and 69T1 to 69T4. In FIG. 14, the first and second inductor conductors L24c and L25c are shown by solid lines and broken lines.

The reference symbol A1 in FIG. 14 denotes an axis passing through a space surrounded by the conductor layers 633, 643, 653, 663, 673, and 683. The first inductor conductor L24c is wound about the axis A1 extending in a first direction.

The reference symbol A2 in FIG. 14 denotes an axis passing through a space surrounded by the conductor layers 601, 711, and 712, and the through holes 60T1 to 60T4, 61T1 to 61T4, 62T1 to 62T4, 63T1 to 63T4, 64T1 to 64T4, 65T1 to 65T4, 66T1 to 66T4, 67T1 to 67T4, 68T1 to 68T4, and 69T1 to 69T4. The second inductor conductor L25c is wound about the axis A2 extending in a second direction intersecting the first direction.

In the present embodiment, the first direction and the second direction are orthogonal to each other. Either one of the first and second directions is parallel to the stacking direction T. In the present embodiment, the first direction is a direction parallel to the Z direction and parallel to the stacking direction T. The axis A1 extends in a direction parallel to the stacking direction T. The second direction is a direction parallel to the X direction. The axis A2 extends in a direction orthogonal to the stacking direction T.

As employed herein, an inductor conductor wound about an axis extending in the direction parallel to the stacking direction T will be referred to as a horizontal inductor conductor. An inductor conductor wound about an axis extending in the direction orthogonal to the stacking direction T will be referred to as a vertical inductor conductor. In the present embodiment, the first inductor conductor L24c is a horizontal inductor conductor. The second inductor conductor L25c is a vertical inductor conductor.

As described above, the bottom surface 50A and the top surface 50B of the stack 50 each have a rectangular shape extending in the X direction. Of the four side surfaces 50C, 50D, 50E, and 50F of the stack 50, the side surfaces 50C and 50D are located at both longitudinal ends of the rectangular shape. As shown in FIG. 14, the second inductor conductor L25c, a vertical inductor conductor, is located closer to the side surface 50C than to the side surface 50D. The distance from the second inductor conductor L25c to the side surface 50C is smaller than the distance from the first inductor conductor L24c, a horizontal inductor conductor, to the side surface 50C.

The stack 50 further includes resonator conductors constituting the resonator 10. The resonator conductors are conductor structures including a plurality of conductor layers constituting the inductors L11 to L13 and the capacitors C11 to C13 and a plurality of through holes connected to the plurality of conductor layers. In FIG. 14, the plurality of conductor layers of the resonator conductors that constitute the inductors L11 to L13 are shown by broken lines. The resonator conductors are located closer to the side surface 50D than to the side surface 50C. The second inductor conductor L25c, a vertical inductor conductor, is thus located farther from the resonator conductors than is the first inductor conductor L24c, a horizontal inductor conductor. The second inductor conductor L25c is also located farther from the plurality of conductor layers constituting the inductors L11 to L13 than is the first inductor conductor L24c.

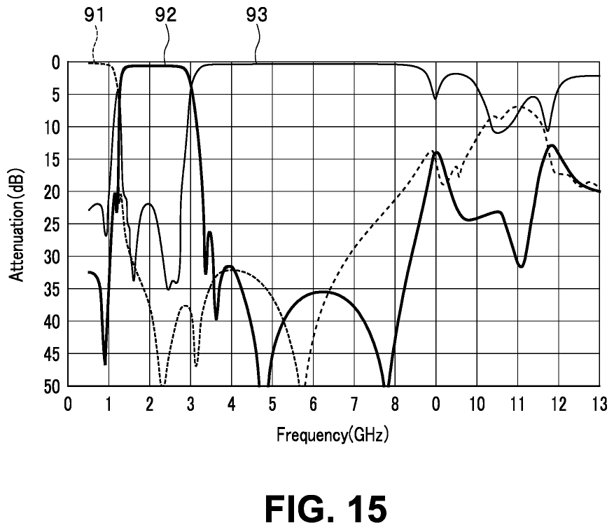

Next, an example of the characteristics of the electronic component 1 according to the present embodiment will be described. FIG. 15 is a characteristic diagram showing an example of pass characteristic and reflection characteristic of the electronic component 1. In FIG. 15, the curve denoted by the reference numeral 91 represents the pass characteristic of the second filter constituted by the resonator 10 provided between the common port 2 and the signal port 3. The curve denoted by the reference numeral 92 represents the pass characteristic of the first filter constituted by the resonator 20 provided between the common port 2 and the signal port 4. The curve denoted by the reference numeral 93 represents the reflection characteristic at the common port 2.

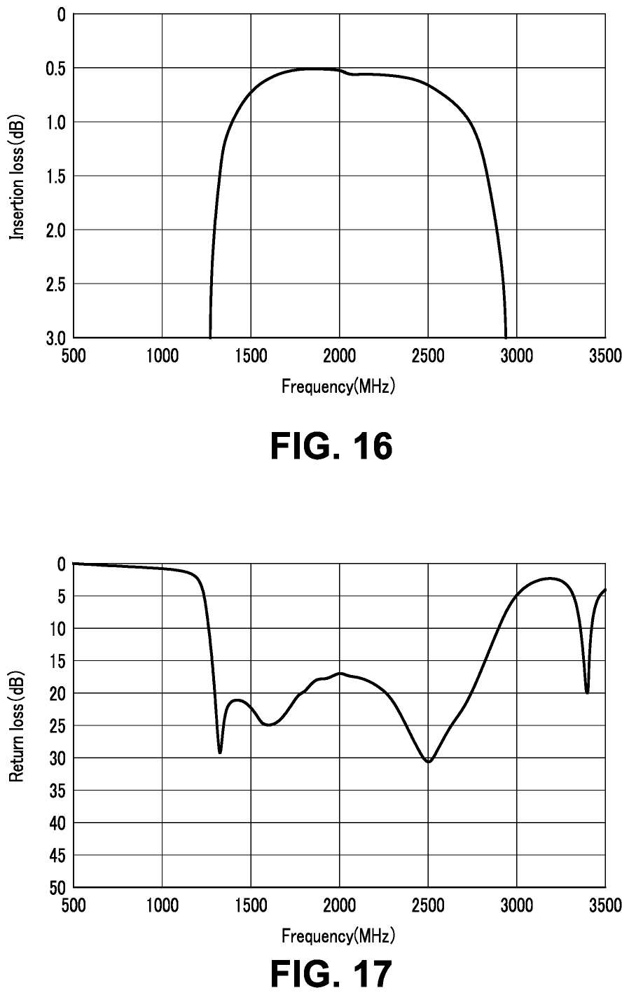

FIG. 16 is a characteristic diagram showing the insertion loss characteristic of the first filter. FIG. 17 is a characteristic diagram showing the return loss characteristic of the first filter. In FIG. 16, the horizontal axis represents frequency, and the vertical axis represents insertion loss. In FIG. 17, the horizontal axis represents frequency, and the vertical axis represents return loss.

Now, the operation and effects of the electronic component 1 according to the present embodiment will be described. As described above, in the present embodiment, the second end of the first inductor L24 is connected to one end of the second inductor L25. As the electronic component 1 is reduced in size, the distance between two inductors adjacent in the circuit configuration, like the first and second inductors L24 and L25, decreases and the electromagnetic coupling between the two inductors increases. The electromagnetic coupling between the two inductors is particularly likely to be strong if the two inductor conductors constituting the two inductors are wound about axes both extending in the same direction and one of the two inductor conductors is located to overlap the other when seen from the axial direction, like the two inductors described in US 2018/0006625 A1.

By contrast, in the present embodiment, the first inductor conductor L24c constituting the first inductor L24 is wound about the axis A1 extending in the first direction, and the second inductor conductor L25c constituting the second inductor L25 is wound about the axis A2 extending in the second direction intersecting the first direction. According to the present embodiment, the electromagnetic coupling between the first inductor L24 and the second inductor L25 can thus be reduced compared with the foregoing case. According to the present embodiment, the electronic component 1 can thus be reduced in size while achieving desired characteristics. Specifically, as shown in FIG. 15, the pass attenuation in a frequency band (approximately 3 to 8 GHz) higher than the first passband can be increased.

In the present embodiment, the first direction and the second direction are orthogonal to each other. According to the present embodiment, the electromagnetic coupling between the first inductor L24 and the second inductor L25 can thereby be further reduced.

Vertical inductor conductors are likely to be electromagnetically coupled with other conductors arranged in the direction orthogonal to the stacking direction T, compared with horizontal inductor conductors. In the present embodiment, the first inductor conductor L24c is a horizontal inductor conductor, and the second inductor conductor L25c is a vertical inductor conductor. The first and second inductor conductors L24c and L25c are arranged in the foregoing positional relationship with the side surface 50C. According to the present embodiment, the distance from the other conductors located on the side surface 50D side can thereby be increased, compared with the case where the distance from the second inductor conductor L25c to the side surface 50C is greater than that from the first inductor conductor L24c to the side surface 50C. As a result, according to the present embodiment, the electromagnetic coupling of the second inductor conductor L25c with the other conductors located on the side surface 50D side can be reduced.

The electronic component 1 according to the present embodiment is a branching filter (diplexer) including the resonator 10 provided between the common port 2 and the signal port 3 and the resonator 20 provided between the common port 2 and the signal port 4. The first and second inductors L24 and L25 are included in the resonator 20. The first and second inductor conductors L24c and L25c are arranged in the foregoing positional relationship with the resonator conductors constituting the resonator 10. According to the present embodiment, the isolation characteristic between the signal ports 3 and 4 can thus be prevented from deteriorating due to the electromagnetic coupling of the second inductor conductor L25c included in the resonator 20 with the resonator conductors constituting the resonator 10.

The present invention is not limited to the foregoing embodiment, and various modifications may be made thereto. For example, the electronic component according to the present invention may be an electronic component including only the resonator 20 or the LC circuit 26 as its circuit component. The electronic component including only the resonator 20 functions as a band-pass filter. The electronic component including only the LC circuit 26 functions as a low-pass filter.

The first and second inductor conductors according to the present invention are also applicable to two inductors other than the inductors L24 and L25 as long as the requirement that the second end of the first inductor be connected to one end of the second inductor is satisfied. Specifically, the first and second inductor conductors according to the present invention can be applied to the inductors L11 and L12 of the resonator 10, or the inductors L22 and L23 of the LC circuit 25 in the resonator 20. The pair of inductors L11 and L12 and the pair of inductors L22 and L23 both satisfy the requirement that the second end of the first inductor be connected to one end of the second inductor.

The second end of the first inductor may be directly or indirectly connected to one end of the second inductor.

Contrary to the embodiment, the first inductor conductor constituting the first inductor L24 may be a vertical inductor conductor, and the second inductor conductor constituting the second inductor L25 may be a horizontal inductor conductor.

Obviously, many modifications and variations of the present invention are possible in the light of the above teachings. Thus, it is to be understood that, within the scope of the appended claims and equivalents thereof, the invention may be practiced in other embodiments than the foregoing most preferable embodiment.

What is claimed is:

1. A multilayer electronic component comprising:
a first port;
a second port that passes a signal input to the first port;
a first inductor and a second inductor that are provided between the first port and the second port in a circuit configuration; and
a stack that includes a plurality of dielectric layers and a plurality of conductors stacked together, the stack being intended to integrate the first port, the second port, the first inductor, and the second inductor, wherein:
the first inductor has a first end closest to the first port in the circuit configuration, and a second end opposite to the first end;
the second end of the first inductor is connected to one end of the second inductor;
the stack includes a first inductor conductor constituting the first inductor, and a second inductor conductor constituting the second inductor;
the first inductor conductor is wound about an axis extending in a first direction; and
the second inductor conductor is wound about an axis extending in a second direction intersecting the first direction.

2. The multilayer electronic component according to claim 1, wherein the first direction and the second direction are orthogonal to each other.

3. The multilayer electronic component according to claim 2, wherein either one of the first and second directions is parallel to a stacking direction of the plurality of dielectric layers.

4. The multilayer electronic component according to claim 1, wherein the first inductor and the second inductor are provided in series in a path connecting the first port and the second port.

5. The multilayer electronic component according to claim 1, further comprising a first resonator provided between the first port and the second port in the circuit configuration, wherein
the first inductor and the second inductor are included in the first resonator.

6. The multilayer electronic component according to claim 5, further comprising:
a third port; and
a second resonator provided between the first port and the third port in the circuit configuration.

7. The multilayer electronic component according to claim 6, wherein:
either one of the second and third ports is a first signal port that selectively passes a first signal of a frequency within a first passband; and
the other of the second and third ports is a second signal port that selectively passes a second signal of a frequency within a second passband lower than the first passband.

8. The multilayer electronic component according to claim 7, wherein the second port is the first signal port, and the third port is the second signal port.

9. The multilayer electronic component according to claim 6, wherein:
the stack further includes a second resonator conductor constituting the second resonator;
either one of the first and second inductor conductors is a horizontal inductor conductor wound about an axis extending in a direction parallel to a stacking direction of the plurality of dielectric layers;
the other of the first and second inductor conductors is a vertical inductor conductor wound about an axis extending in a direction orthogonal to the stacking direction of the plurality of dielectric layers; and
the vertical inductor conductor is located farther from the second resonator conductor than is the horizontal inductor conductor.

10. The multilayer electronic component according to claim 6, wherein:
the stack has a bottom surface and a top surface located at both ends of the plurality of dielectric layers in a stacking direction, and four side surfaces connecting the bottom surface and the top surface;
the bottom surface and the top surface each have a rectangular shape extending in one direction;
the four side surfaces include a first side surface and a second side surface located at both longitudinal ends of the rectangular shape;
either one of the first and second inductor conductors is a horizontal inductor conductor wound about an axis extending in a direction parallel to the stacking direction of the plurality of dielectric layers;
the other of the first and second inductor conductors is a vertical inductor conductor wound about an axis extending in a direction orthogonal to the stacking direction of the plurality of dielectric layers;
the vertical inductor conductor is located closer to the first side surface than to the second side surface;
a distance from the vertical inductor conductor to the first side surface is smaller than a distance from the horizontal inductor conductor to the first side surface.
